(19) United States
(12) Patent Application Publication
(10) Pub. No.: US 2026/0060103 A1
(43) Pub. Date: Feb. 26, 2026

(54) Sintered Power Electronic Module

(71) Applicant: Siemens Aktiengesellschaft, München (DE)

(72) Inventors: Jörg Strogies, Berlin (DE); Christian Nachtigall-Schellenberg, Nuthe-Urstromtal (DE); Thomas Bigl, Herzogenaurach (DE); Matthias Heimann, Potsdam (DE); Stefan Pfefferlein, Heroldsberg (DE); Alexander Hensler, Gerhardshofen (DE); Bernd Müller, Falkenberg (DE)

(73) Assignee: Siemens Aktiengesellschaft, München (DE)

(21) Appl. No.: 19/102,814

(22) PCT Filed: Jul. 14, 2023
(86) PCT No.: PCT/EP2023/069649

§ 371 Date: Feb. 10, 2025

(30) Foreign Application Priority Data
Aug. 11, 2022 (EP) 22189873.7

(51) Int. Cl. H01L 23/00; H01L 23/498; H01L 23/538; H01L 25/07

(52) U.S. Cl. CPC H01L 24/32; H01L 23/49811; H01L 23/5385; H01L 24/81; H01L 24/83; H01L 25/072; H01L 24/16; H01L 24/27; H01L 24/73; H01L 2224/16227; H01L 2224/16238; H01L 2224/27505; H01L 2224/32227; H01L 2224/32238; H01L 2224/73203; H01L 2224/73253; H01L 2224/81203; H01L 2224/83203; H01L 2924/13055; H01L 2924/13091; H01L 2924/35

(57) ABSTRACT

Various embodiments of the teachings herein include a sintered power electronic module with a first plane and a second plane different from the first plane. An example comprises: a first substrate with a first metallization arranged on the first plane; a second substrate with a second metallization arranged on the second plane; a switchable die having a first power terminal and a second power terminal, the die arranged between the first substrate and the second substrate; and a surface area of all the sintered connections of the first plane is between 90 and 110% of a surface area of all the sintered connections of the second plane. The first power terminal of the die is joined to the first metallization via a sintered connection in the first plane and the second power terminal is joined to the second metallization via a sintered connection in the second plane.

### CROSS-REFERENCE TO RELATED APPLICATIONS

This application is a U.S. National Stage Application of International Application No. PCT/EP2023/069649 filed Jul. 14, 2023, which designates the United States of America, and claims priority to EP Application No. 22189873.7 filed Aug. 11, 2022, the contents of which are hereby incorporated by reference in their entirety.

### TECHNICAL FIELD

The present disclosure relates to power electronics. Various embodiments of the teachings herein include sintered power electronic modules and methods for producing sintered connections of a power electronic module.

### BACKGROUND

A sintered power electronic module may be used, for example, in industrial converters and in electric vehicles. Power electronics assembly systems with different joining planes can be joined metallurgically to achieve electrical/thermal and mechanical connections. Due to design and production requirements, pressure sintered connections made of Ag or soft solder connections are primarily used to realize these joining planes. Pressure sintered connections may have preferred properties in terms of their electrical and high-temperature properties. Here, a challenge is presented by the necessary processing using mechanical pressure, typically in the range of around 10-20 MPa, and the need for elevated temperatures. With sintering in a plurality of planes and more complex structures, the arrangement consists of effective joining zones that are aligned either parallel and/or in series with respect to force and pressure.

### SUMMARY

The teachings of the present disclosure include providing a power module that is sintered completely and in a plurality of planes and can be sintered in one working step. For example, some embodiments of the teachings herein include a sintered power electronic module (100) with a first plane (E1) and a second plane (E2) that differs from the first plane (E1), having: a first substrate (10) with a first metallization (12), which is arranged on the first plane (E1), a second substrate (20) with a second metallization (22), which is arranged on the second plane (E2), one or more switchable dies (40), which each have at least one first power terminal (42) and at least one second power terminal (44), wherein the dies (40) are arranged between the first substrate (10) and the second substrate (20) and the first power terminal (42) of the dies is joined to the first metallization (12) via a first sintered connection (31) in the first plane (E1) and the second power terminal (44) of the dies is joined to the second metallization (22) via a second sintered connection (32) in the second plane (E2) (22) and wherein a surface area (A1) of all the sintered connections (31) of the first plane (E1) is between 90 and 110%, in particular between 95% and 105%, of a surface area (A2) of all the sintered connections (32) of the second plane (E2).

As another example, some embodiments include a power electronic module (100) further having at least one electrically conductive interconnection (50), which connects an electrical potential of the first plane (E1) to the second plane (E2), wherein the interconnection (50) is contacted with the first and the second metallization (12, 22) via compensating sintered connections (36, 38), which have different surface areas.

In some embodiments, the interconnection (50) has a first contact surface and a second contact surface which have different surface areas from one another.

In some embodiments, power electronic module (100) includes at least two switchable dies (40), each of which have sintered connections (31, 32) to the metallizations (12, 22).

In some embodiments, the power electronic module (100) includes at least two switchable dies (40) with control terminals (45), which are arranged differently with respect to their control terminals (45) and the plane (E1, E2) adjacent thereto.

In some embodiments, the power electronic module (100) has one or more electrically insulating compensating elements arranged such that the sum of the surface areas of all the sintered connections (32) and the compensating elements in the first plane (E1) corresponds to the sum of the surface areas of all the sintered connections (32) and compensating elements in the second plane (E2), taking into account a maximum deviation of 10%.

In some embodiments, the power electronic module (100) has a third plane (E3) that differs from the first plane (E1) and the second plane (E2), wherein, in the third plane (E3), third sintered connections (33) contact terminal elements (70) with a second metallization (27) of the second substrate (20).

In some embodiments, the sintered connections (31, 32) are embodied as pressure sintered connections.

As another example, some embodiments include a method for producing sintered connections of a power electronic module (100) in the form of a stack in at least a first plane (E1) and a second plane (E2) that differs from the first plane (E1), comprising: providing a first substrate (10) with a first metallization (12), which is arranged on the first plane (E1), a second substrate (20) with a second metallization (22), which is arranged on the second plane (E2) and one or more switchable dies (40), which are arranged between the first substrate (10) and the second substrate (20) and each have at least one first power terminal (42) and at least one second power terminal (44), providing sintered material in the first plane (E1), which contacts the first power terminals (42) to the first metallization (12) and sintered material in the second plane (E2), which contacts the second power terminal (44) to the second metallization (22), wherein a surface area of the sintered material in the first plane (E1) corresponds to at least 90% and at most 110% of a surface area of the sintered material in the second plane (E2), and applying a force (F) at a temperature (T) to the stack so that a pressure is established in the sintered materials of the first and the second plane (E1, E2), which leads to the formation of first and second sintered connections (31, 32) from the sintered materials.

In some embodiments, the force (F) is established such that a pressure of at least 10 MPa, in particular at least 15 MPa, is established in the sintered materials of the first and the second plane (E1, E2).

In some embodiments, the surface area of the sintered material in the first plane (E1) and in the second plane (E2) is selected such that the pressure in the planes (E1, E2) differs by a maximum of 1 MPa.

In some embodiments, the force (F) is applied to the entire stack with a punch (200).

In some embodiments, prior to the application of the force (F), compensating elements (80, 82) are arranged such that bulging of at least one of the substrates (10, 20) is reduced.

In some embodiments, the force F for producing the sintered connections is applied continuously until the sintered connections are completed in both planes.

In some embodiments, a maximum of 180 seconds elapses from the application of the force F until the completion of all the sintered connections (31, 32) in all the planes.

### BRIEF DESCRIPTION OF THE DRAWINGS

The following describes the teachings of the present disclosure in more detail with reference to the exemplary embodiments depicted in the figures, which show:

FIG. 1 an embodiment of a power electronic module incorporating teachings of the present disclosure;

FIG. 2 a section through the first plane in plan view;

FIG. 3 a section through the second plane in plan view;

FIG. 4 a further embodiment of the power electronic module in a sintering press incorporating teachings of the present disclosure; and

FIG. 5 a force curve in the power electronic module in pressed state.

### DETAILED DESCRIPTION

Various embodiments of the teachings here include a sintered power electronic module with a first plane and a second plane that differs from the first plane has a first substrate with a first metallization that is arranged on the first plane, a second substrate with a second metallization that is arranged on the second plane and one or more switchable dies, which each have at least one first power terminal and at least one second power terminal. Herein, the dies are arranged between the first substrate and the second substrate and in each case the first power terminal of the dies is joined to the first metallization via a first sintered connection in the first plane and the second power terminal of the dies is joined to the second metallization via a second sintered connection in the second plane. To achieve a constant pressure in the tolerable range during sintering, a surface area of all the sintered connections in the first plane is between 90 and 110%, in particular between 95% and 105%, of a surface area of all the sintered connections in the second plane. The power module defined in this way can be sintered in one process step and can therefore be manufactured more easily.

The surface area should be understood as being the cross-sectional area of the sintered connection that is relevant to the pressure in the surface. Therefore, in simplified terms, the cross-sectional areas of the sintered connections can be used. Since the presses used for sintering are force-controlled, it is important that the module is designed in such a way that the pressures generated in the sintered connections or their precursor sintered materials lead to a high-quality sintered connection. Equalization of the surface areas of the sintered connections leads to a uniform pressure distribution in the individual sintered connections when a constant force is applied to the entire module or stack.

The switchable die is a semiconductor component, which can, for example, be embodied as an IGBT or MOSFET. This is an unhoused semiconductor and is also referred to as a bare die or a bare chip. Herein, so-called “wide bandgap” semiconductors may be used. Herein, the substrates can be embodied as metal-ceramic substrates. In particular, so-called direct-bonded copper substrates and active metal brazing substrates should be mentioned in this context. Furthermore, it is possible to use plastic printed circuit boards as one of the substrates, for example, fiber-reinforced plastic printed circuit boards, such as FR4 printed circuit boards, so-called high Tg PCBs (with a glass transition temperature TG of greater than 150° C.), made of polyimide and/or designed as a pre-molded leadframe. High-temperature interposer materials, such as, for example, PI, PEEK or LCP have proven suitable for high-temperature applications.

In some embodiments, the power electronic module has at least one electrically conductive interconnection which connects the electrical potential of the first plane to the second plane. The interconnection is contacted with the first and the second metallization via compensating sintered connections, which have different surface areas. This enables differences in the surface areas of the sintered connections in the first and the second plane to be compensated, so that a uniform pressure is established in both planes and the sintered connections are accordingly of high quality.

In some embodiments, the interconnection has a first contact surface and a second contact surface, which have different surface areas from one another. The shape of the interconnection can thus contribute to better force guidance and introduce the force into the differently sized sintered connections more effectively.

In some embodiments, the power electronic module has at least two switchable dies, each of which have sintered connections to the metallizations. The architecture may be advantageous if a plurality of dies is arranged, since this allows optimum distribution of the pressure to be achieved and the number of dies required for the application to be sintered.

In some embodiments, the power electronic module has at least two switchable dies with control terminals. The dies are arranged differently with respect to the control terminals and the plane adjacent thereto. In other words, the dies can in each case be arranged with alternating top and bottom sides. Herein, the alternation does not need to be strictly sequential; the aim is that the dies are arranged such that the surface area of the sintered connections in the first plane corresponds as closely as possible to the surface area of the sintered connections in the second plane. Since the top and bottom sides of the chip have different contact surfaces, here, alternating the chip orientation is one way of further equalizing the surface area of the sintered connections.

In some embodiments, the power electronic module has one or more electrically insulating compensating elements arranged such that the sum of the surface areas of all the sintered connections and the compensating elements in the first plane corresponds to the sum of the surface areas of all the sintered connections and the compensating elements in the second plane taking into account a maximum deviation of 10%. The electrically insulating compensating elements can thus further equalize the surfaces, since the pressure resulting from the force and surfaces acts on these as well as on the sintered connections. Herein, the compensating elements can protrude through both planes and be in mechanical contact with both metallizations of the substrates.

In some embodiments, the power electronic module has a third plane that differs from the first plane and the second plane. In the third plane, third sintered connections contact a second metallization of the second substrate with terminal elements. Herein, the terminal elements can be metallic terminal elements for thermal and/or electrical contacting of the module with heat sinks or power terminals.

In some embodiments, the sintered connections are embodied as pressure sintered connections. The structure of the module enables pressure sintered connections to be produced in one working step in a plurality of planes. Here, the sintered materials used can, for example, be silver-based pressure sintering pastes and preforms.

Some embodiments include a method for producing sintered connections of a power electronic module in the form of a stack in at least a first plane and a second plane that differs from the first plane. An example method comprises: providing a first substrate with a first metallization that is arranged on the first plane, a second substrate with a second metallization that is arranged on the second plane and one or more switchable dies, which are arranged between the first substrate and the second substrate, and in each case have at least one first power terminal and at least one second power terminal, providing sintered material in the first plane, which contacts the first power terminals to the first metallization, and sintered material in the second plane, which contacts the second power terminal to the second metallization. Herein, a surface area of the sintered material in the first plane corresponds to at least 90% and at most 110%, in particular 95% to 105%, of a surface area of the sintered material in the second plane, and applying a force at a temperature to the stack, so that a pressure is established in the sintered materials of the first and the second plane that leads to the formation of first and second sintered connections from the sintered materials. Herein, the sintered connections in the different planes can be formed simultaneously or overlapping with a slight offset. The sintered material can be applied as a preform, as a screen print or in other conventional forms.

When the force is applied, for example by a sintering press, a pressure is established in the individual sintered connections in dependence on the cross-sectional areas of the sintered materials.

Due to the method according to the invention, the pressure is similar in both planes due to the approximation of the surface areas, thus guaranteeing completion and high quality of the sintered connections in both planes.

Herein, the embodiments of the power electronic module are in particular applicable to the method with regard to the arrangement of the sintered connections (or the sintered material in the state before joining) and the area of the sintered material in the planes. Herein, the method is may be used to produce a power electronic module according to one or more of the embodiments as described in the introduction.

In some embodiments, the force is set such that a pressure of at least 10 MPa, in particular at least 15 MPa, is established in the sintered materials of the first and the second plane. Herein, a pressure range of 10 to 20 MPa can be regarded as normal. If an average pressure range of approximately 15 MPa (12 to 18 MPa) is selected, larger deviations can be tolerated and the sintered connections are formed satisfactorily and the dies are not exposed to excessive pressure. A temperature range of around 250° C. (220 to 280° C.) has proven to be advantageous.

In some embodiments, the surface area of the sintered material in the first plane and in the second plane is selected such that the pressure in the planes differs by a maximum of 1 MPa. The relationship of area, force and pressure enables the pressure in the planes to be established so that it only differs by permissible values. Requirements for the sintering press can thus be reduced.

In some embodiments, the force is applied to the entire stack with a punch. The arrangement of the stack and the dimensions of the sintered materials enable the entire stack to be sintered in a single pressing process.

In some embodiments, prior to the application of the force, compensating elements are arranged such that bulging of at least one of the substrates is reduced. If one of the substrates extends over a larger area than the other substrate, compensating elements can be arranged temporarily for the pressing process. These compensating elements should preferably be arranged such that they are in direct contact with the press on one side. This enables an even distribution of force on parts of the module that are not in direct mechanical contact in the press.

In some embodiments, the force F for producing the sintered connections is applied continuously until the sintered connections are completed in both planes. In other words, the force F can be applied to the entire stack without settling, and the sintered connections are completed in all planes by the pressure that can be established with the surface areas.

In some embodiments, a maximum of 180 seconds elapses between the application of the force F and the completion of the sintered connections in all planes. The method enables the process time for finalizing sintered connections to be significantly reduced, since it is possible to save not only the intermediate steps after sintering in a single plane, such as reapplying sintering material, but also the sequential durations of the actual sintering process. It is conceivable that the sintering process may take slightly longer in a plurality of planes than in a single plane, but the time advantage may be nevertheless substantial.

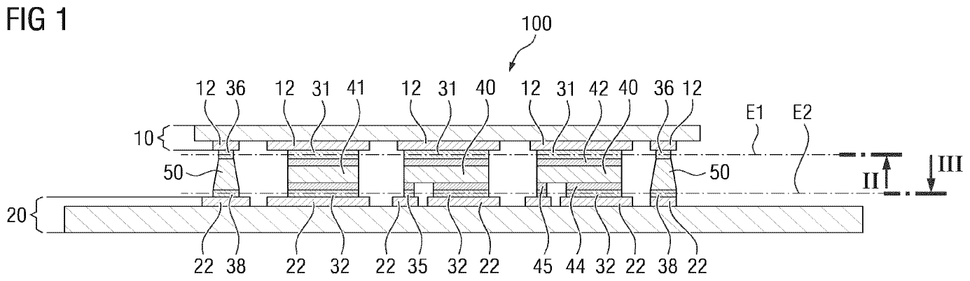

FIG. 1 shows an exemplary embodiment of a power electronic module 100 incorporating teachings of the present disclosure, with a first plane E1 and a second plane E2 that differs from the first plane E1. Herein, the planes E1 and E2 are arranged parallel to a first substrate 10 and a second substrate 20 of the module 100. The first substrate 10 has a first metallization 12 which is arranged on the first plane E1 and is arranged facing a second metallization 22 of the second substrate 20. The second substrate 20 is arranged with its second metallization 22 on the second plane E2. In the present case, two switchable dies 40 are arranged between the metallizations 12, 22 each of which have a first power terminal 42 and a second power terminal 44.

The dies 40 each have a control terminal 45. Herein, the first power terminals 42 are connected to the first metallization 12 via first sintered connections 31. The first metallization 12 is structured such that the electrical components can form a functional unit. For example, joining surfaces are provided on the metallization. Similarly, the second power terminals 44 are connected to the second metallization 22 via second sintered connections 32. The second metallization is structured in the same way.

In the present case, the control terminals 45 are joined to the second metallization 22 via joint connections 35. However, the control terminals could also be joined to the first metallization 12 or differently to the first and second metallization 12, 22. Depending on their size, the joint connections can also be sintered or embodied as a solder connection, which is also created during sintering.

For example, the power module 100 can be embodied as a half-bridge, full-bridge or so-called six pack, each with one or more dies 40 for each functional switch (for example depending on whether MOSFETS or IGBTs are used). A further electronic component 41 has two terminals and, like the dies 40, is arranged between the metallizations 12, 22.

The dies 40 and the further electronic component 41 are each connected to the substrates 10, 20 or the metallizations 12, 22 thereof via sintered connections.

Furthermore, Electrically Conductive Interconnections 50 With compensating sintered connections 36, 38 are arranged such that a surface area of all the sintered connections in the first plane E1 approaches the surface area of all the sintered connections in the second plane E2. In the present case, the compensating sintered connection 36 arranged above the interconnection 50 is embodied as smaller than the compensating sintered connection 38 arranged below the interconnection 50. The size of the compensating sintered connections 36, 38 can be freely selected if they exceed the required minimum size (for example specified by the current carrying capacity). Herein, the interconnection 50 can be a copper molded part, which can, for example, be embodied as a cuboid or truncated pyramid with at least two parallel joining surfaces. Herein, the size of the compensating sintered connections 36, 38 does not need to correspond to the size of the surfaces of the interconnection on which they rest, it can also be selected as smaller.

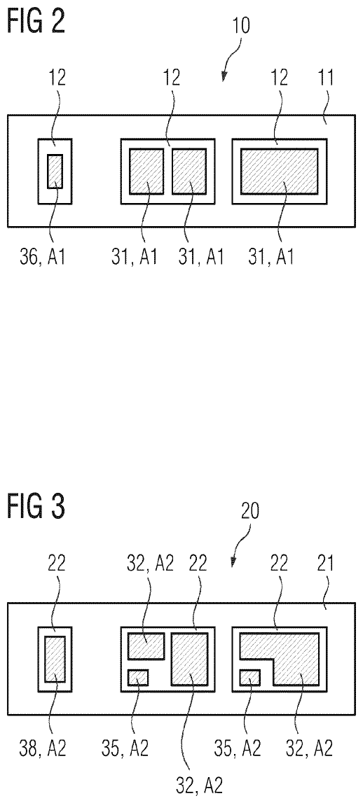

FIG. 2 Shows a Schematic Section Through the First Plane E1 of the power electronic module 100 in plan view, wherein the first substrate 10 made of a substrate material 11 with its first metallization 12 and the joining surfaces formed therefrom can be seen. For the sake of simplicity, only joining surfaces of one of the interconnections 50 and the two dies 40 from FIG. 1 are shown. The first sintered connections 31, the power terminals of the dies 40 and the compensating sintered connection 36 can be seen on the metallization 12. All the sintered connections 31, 36 contribute to the surface area A1 of the sintered connections, since, due to the force of the sintering press, a pressure is established that creates the sintered connections from the sintered materials used.

Herein, the Middle Joining Surface of the Metallization 12 Has Two separate sintered connections 31 which are embodied as corresponding to the first power terminals 42 of the respective die 40. Dies often have separate surfaces for the power terminals which are at the same potential. This depends on the design and make of the dies.

The compensating sintered connection 36 has a smaller surface than the existing joining surface of the metallization 12, this shows that the surface A1 of the sintered connections can be adapted here.

Analogously to FIG. 2, FIG. 3 shows a schematic section through the second plane E2 of the power electronic module 100 in plan view, wherein the second substrate 20 made of a substrate material 21 with its second metallization 12 and the joining surfaces formed therefrom can be seen. Second sintered connections 32, a compensating sintered connection 38 and a joint connection 35 of a control terminal (for example gate or collector) of the die 40 contribute to the second surface A2.

It can be seen that, due to the design of the dies 40 and also due to the joint connections 35 of the control terminals 45, the second sintered connections 32 have a smaller surface than the first sintered connections 31 on the other side of the die, i.e., in plane E1, as shown in FIG. 2. Herein, the middle joining surface has two second joint connections 32; power terminals divided in this way are common in some dies. The right joining surface of the metallization 22

Furthermore, it can be seen that the compensating sintered connection 38 in the second plane E2 has a larger surface than the compensating sintered connection 36 in FIG. 2 in the first plane E1.

Thus, by selecting the surfaces of the compensating sintered connections 36, 38, it is possible, in addition to or as an alternative to arranging the dies and further components, to match the surface areas A1, A2 of sintered connections in the planes E1, E2 to one another.

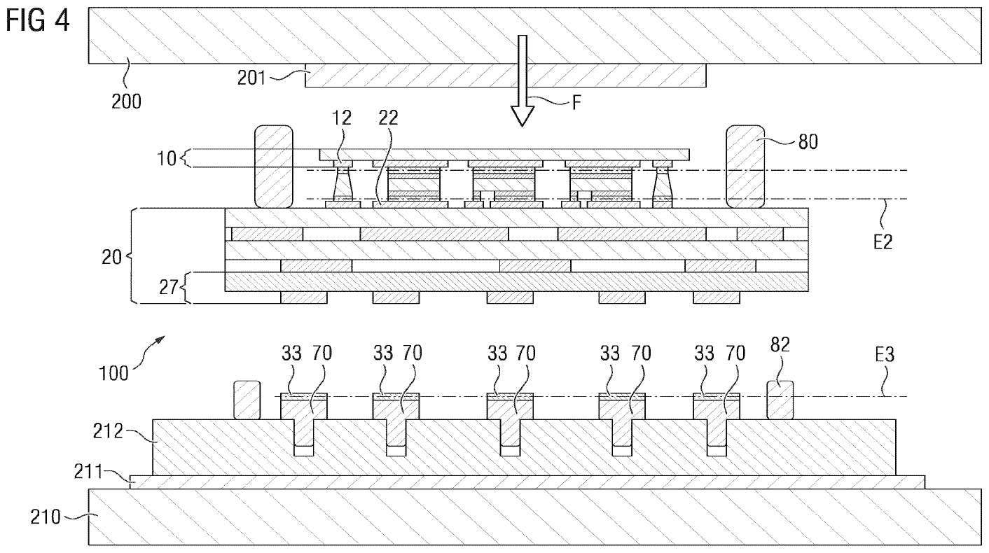

FIG. 4 shows a further example power electronic module 100 incorporating teachings of the present disclosure, shown between the tools of a sintering press. Herein, the power electronic module 100 is based on the embodiment shown in FIG. 1 and has been expanded on the second substrate 20.

Herein, the sintering press has a punch 200 with a support 201, which is intended to exert a force F from above onto the module 100. The second substrate 20 has several layers and a second metallization 27. Herein, the second metallization 27 is used to connect terminal elements 70, which are joined to the second metallization 27 by third sintered connections 33 in a third plane E3. In the present case, the terminal elements 70 are embodied as metal pins, which can provide both thermal and electrical connections. Herein, the pins can, for example, be pressed in.

A lower tool 210 serves as a counterpart to the punch 200 and has an adapter plate 212 mounted on a support 211. In this case, the adapter plate has recesses adapted to the second substrate 20 or the terminal elements 70 attached thereto.

Herein, the third sintered connections 33 in the third plane E3 have a surface area, which may differ from the surface areas A1, A2 of the sintered connections 31, 32 in the first and the second planes E1, E2. The difference in surface areas would lead to a difference in pressure during pressure sintering so that, in the present example, compensating elements 80, 82 are provided. Herein, the compensating elements can be used to distribute the force F more evenly over the surface. Herein, when the sintering press is closed, the first compensating elements 80 are only in contact with the punch 200 and the side of the second substrate 20 facing the punch 200. Herein, the surface areas of the cross sections of the compensating elements 80, 82 in the different planes E1, E2, E3 can be used to equalize the sum of the surface areas in the respective plane to the further planes and thus to equalize the pressure during joining. Moreover, it is advantageously also possible to avoid or reduce bulging in the case of differently sized first and second substrates 10, 20.

Analogously to the First Compensating Elements 80, Second compensating elements 82 are arranged below the second substrate 20 in order to reduce an overhang that the second substrate 20 has with respect to the terminal elements 70. Herein, the compensating elements can be used multiple times and do not need to remain on the power electronic module 100. It is conceivable that compensating elements (not shown) are arranged and integrated in such a way that they can remain on/in the module 100.

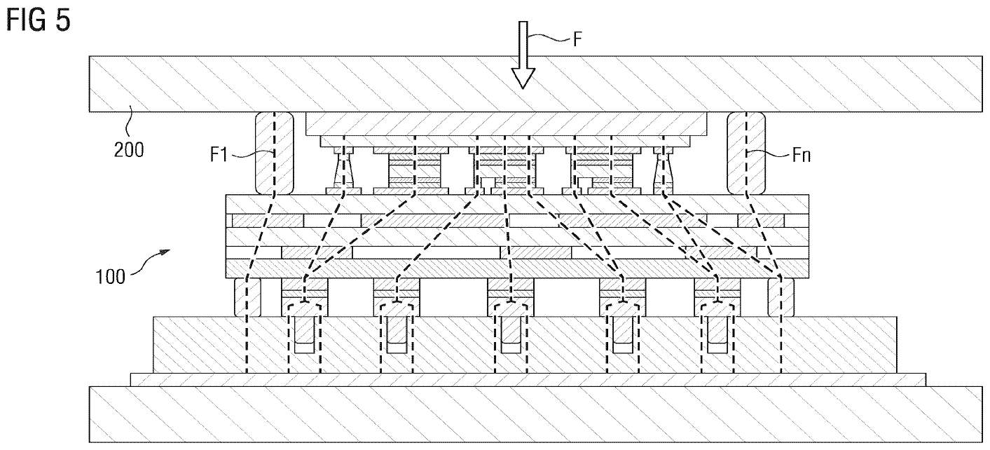

FIG. 5 now shows the embodiment from FIG. 4, wherein the sintering press is closed. Thus, the punch 200 exerts a force F onto the power electronic module 100. Herein, the division of the force F into individual force paths F1, . . . , Fn, which are shown in dashed lines, defines the pressure generated in each case. The introduction of force can be optimized by the design and process engineering measures disclosed in this invention, so that pressure sintering is improved in a plurality of planes. This results in considerable time saving compared to sequential sintering.

The present disclosure shows sintered power electronic modules 100 with a first plane E1 and a second plane E2 that differs from the first plane E1. To provide a power module that is sintered completely and in a plurality of planes and can be sintered in one working step, a method may include: a first substrate 10 with a first metallization 12 that is arranged on the first plane E1, a second substrate 20 with a second metallization 22 that is arranged on the second plane E2, one or more switchable dies 40, which each have at least one first power terminal 42 and at least one second power terminal 44, wherein the dies 40 are arranged between the first substrate 10 and the second substrate 20 and the first power terminal 42 of the dies is joined to the first metallization 12 via a first sintered connection 31 in the first plane E1 and the second power terminal 44 of the dies is joined to the second metallization 22 via a second sintered connection 32 in the second plane E2 and wherein a surface area A1 of all the sintered connections 31 of the first plane E1 is between 90 and 110%, in particular between 95% and 105%, of a surface area A2 of all the sintered connections 32 of the second plane E2.

### List of Reference Symbols

100 Sintered power electronic module
10, 20 First/second substrate
11 Substrate material
12, 22 Metallization of the first/second substrate
27 Second metallization of the second substrate
31 First sintered connections
32 Second sintered connections
33 Third sintered connections
35 Joint connection of the control terminal
36, 38 Compensating sintered connections
40 Switchable die
42,44 Power terminals of the dies
45 Control terminal of the dies
50 Interconnection
70 Terminal elements
80, 82 Compensating elements
E1, E2 First and second plane
A1, A2 Surface area of all the sintered connections in the first or second plane
F1, . . . , Fn Force paths
200 Punch of a sintering press
201 Support for the punch
210 Lower tool of the sintering press
211 Support for the lower tool
212 Adapter plate for the lower tool

What is claimed is:

1. A sintered power electronic module with a first plane and a second plane different from the first plane, the module comprising:
a first substrate with a first metallization arranged on the first plane;
a second substrate with a second metallization is arranged on the second plane;
switchable die having a first power terminal and a second power terminal,
the die arranged between the first substrate and the second substrate; and
wherein the first power terminal of the die is joined to the first metallization-via a first sintered connection in the first plane and the second power terminal of the dies is joined to the second metallization via a second sintered connection in the second plane and
a surface area of all the sintered connections of the first plane is between 90 and 110%, of a surface area of all the sintered connections of the second plane.

2. The power electronic module as claimed in claim 1, further comprising an electrically conductive interconnection connecting an electrical potential of the first plane to the second plane;
wherein the interconnection contacts the first and the second metallization via compensating sintered connections with different surface areas.

3. The power electronic module as claimed in claim 2, wherein the interconnection includes a first contact surface and a second contact surface with different surface areas from one another.

4. The power electronic module as claimed in claim 1, having at least two switchable dies, each with sintered connections to the metallizations.

5. The power electronic module as claimed in claim 1, having at least two switchable dies, with control terminals arranged differently with respect to their control terminals and the plane adjacent thereto.

6. The power electronic module as claimed in claim 1, further comprising one or more electrically insulating compensating elements arranged such that a sum of the surface areas of all the sintered connections and the compensating elements in the first plane corresponds to sum of the surface areas of all the sintered connections and compensating elements in the second plane with a maximum deviation of 10%.

7. The power electronic module as claimed in claim 1, having a third plane different from the first plane and the second plane;
further comprising third sintered connections contacting terminal elements with a second metallization of the second substrate in the third plane.

8. The power electronic module as claimed in claim 1, wherein the sintered connections comprise pressure sintered connections.

9. A method for producing sintered connections of a power electronic module in the form of a stack in at least a first plane and a second plane different from the first plane, the method comprising:
providing a first substrate with a first metallization arranged on the first plane, a second substrate with a second metallization arranged on the second plane and one or more switchable dies arranged between the first substrate and the second substrate and each with at least one first power terminal and at least one second power terminal;
applying sintered material in the first plane contacting the first power terminals to the first metallization; and
applying sintered material in the second plane contacting the second power terminal to the second metallization;
wherein a surface area of the sintered material in the first plane corresponds to at least 90% and at most 110% of a surface area of the sintered material in the second plane; and
applying a force at a temperature to the stack so that a pressure is established in the sintered materials of the first and the second plane leading to the formation of first and second sintered connections with the sintered materials.

10. The method as claimed in claim 9, wherein the force creates a pressure of at least 10 MPa, in the sintered materials of the first and the second plane.

11. The method as claimed in claim 9, wherein the surface area of the sintered material in the first plane and in the second plane is selected such that the pressure in the planes differs by a maximum of 1 MPa.

12. The method as claimed in claim 9, wherein the force is applied to the entire stack with a punch.

13. The method as claimed in claim 9, further comprising, prior to the application of the force arranging compensating elements such that bulging of at least one of the substrates is reduced.

14. The method as claimed in claim 9, wherein the force is applied continuously until the sintered connections are completed in both planes.

15. The method as claimed in claim 9, wherein a maximum of 180 seconds elapses from the application of the force until the completion of all the sintered connections in all the planes.
